(19) United States
(12) Patent Application Publication
(10) Pub. No.: US 2026/0297751 A1
(43) Pub. Date: Oct. 1, 2026

(54) A METHOD FOR OPERATING A CHEMICAL VAPOR DEPOSITION PROCESS

(71) Applicant: CANATU FINLAND OY, Vantaa (FI)

(72) Inventors: Arun HARIDAS CHOOLAKKAL, Linköping (SE); Henrik PEDERSEN, Stigtomta (SE); Jens BIRCH, Linköping (SE)

(21) Appl. No.: 18/880,333

(22) PCT Filed: Jun. 22, 2023
(86) PCT No.: PCT/EP2023/067035

§ 371 Date: Dec. 31, 2024

(30) Foreign Application Priority Data
Jul. 4, 2022 (SE) 2250842-8

(51) Int. Cl. C23C 16/52; C23C 16/04

(52) U.S. Cl. CPC C23C 16/52; C23C 16/045

(57) ABSTRACT

A method for operating a chemical vapor deposition, CVD, process, including providing a substrate in a reaction zone of a reaction chamber, providing at least one precursor gas flow into the reaction chamber, the precursor gas including precursor molecules, heating the reaction chamber to a temperature that is greater than a reaction onset temperature of the precursor molecules, and providing at least one inert diffusion additive gas into the reaction chamber, the inert diffusion additive including inert diffusion additive molecules, wherein the inert diffusion additive molecules have a greater molecular mass than the precursor molecules, and wherein a partial pressure of the inert diffusion additive gas is greater than a partial pressure of the precursor gas. Further a protective layer may be disposed on a substrate having at least one high aspect ratio feature.

### TECHNICAL FIELD

This document relates to chemical vapor deposition, CVD, processes, and in particular to a method of operating a CVD process in order to achieve improved distribution of a coating on a planar surface and/or in order to coat or fill a high aspect ratio feature, such as a trench or a bottom hole in a substrate.

### BACKGROUND

Chemical vapor deposition, CVD, processes find many applications in e.g. the manufacture of semiconductor products. The quality of the deposited layer produced is essential to achieve good material characteristics suitable for use for the intended purposes.

In addition to the general challenge of providing an even coating on a substrate, there is a particular challenge in CVD processes to provide coatings on porous structures and on high aspect ratio type features, such as trenches and bottom holes.

A coating can grow on a substrate in different manners and by calculating the step-coverage of a deposited layer, the manner in which the growth has been performed can be determined. The thickness of the covering layer at the bottom of the trench or hole is divided by the thickness of the deposited layer at the top of the trench or hole to calculate the step-coverage. A step-coverage smaller than 1, indicates that a sub-conformal growth has occurred. Desirable is to have a conformal growth of the deposited layer, which is indicated by a step coverage equal to 1.

For some applications, however, it is desired to completely fill the trench or hole in the substrate with the material deposited. For sub-conformal growth this will most probably lead to the formation of a cavity in the bottom of the trench or hole, since the deposited layer of the top is growing faster than the material growth in the bottom and thus closing the inlet for the deposition material to be able to reach the bottom. The same can occur for conformal growth.

It is particularly challenging to completely fill a trench or a bottom hole having a high aspect ratio. Therefore, it would be desirable to have a deposition with super-conformal growth, i.e., where the step coverage is greater than 1. When growing a super-conformal layer, the material layer thickness increases faster at the bottom of the trench or hole which leads to a layer with a V-shaped form as an intermediate product. When filling a structure by super-conformal growth, the lowest part of the V-shape will move upwards as the layer is growing, until the structure is completely filled.

Super-conformal growth can however be challenging due to that it is hard to maintain a uniform incident flux over a high aspect ratio feature in a typical CVD process due to precursor partial pressure drop along the trench depth. To overcome this, CVD processes have been performed at reduced temperatures to reduce reaction probability to promote more gas phase diffusion and achieving a better film conformality. However, reducing the temperature compromises with the result of the material density of the deposited layer.

A process for growth of a material layer having better material characteristics is therefor of great interest.

### SUMMARY

It is an objective of the present disclosure to provide a method which provides a process for deposition of a protective layer having good material characteristics and surface coverage.

The invention is defined by the appended independent claims, with embodiments being set forth in the appended dependent claims, in the following description and in the appended drawings.

According to a first aspect, there is provided a method for operating a chemical vapor deposition, CVD, process, comprising providing a substrate in a reaction zone of a reaction chamber, providing at least one precursor gas flow into the reaction chamber, the precursor gas comprising precursor molecules, heating the reaction chamber to a temperature that is greater than a reaction onset temperature of the precursor molecules, and providing at least one inert diffusion additive gas into the reaction chamber, the inert diffusion additive comprising inert diffusion additive molecules, wherein the inert diffusion additive molecules have a greater molecular mass than the precursor molecules, and wherein a partial pressure of the inert diffusion additive gas is greater than a partial pressure of the precursor gas.

The inert diffusion additive gas, having a higher partial pressure than the precursor gas, and due to its molecules having a greater molecular mass and therefore having a lower diffusion rate in comparison with the precursor gas, will promote more gas diffusion of the precursor gas resulting in a better surface coverage of the substrate. Hence, there is provided an improved chemical vapor deposition process.

The CVD process may be a continuous process.

The CVD process may be a thermal CVD process.

The CVD process may be a plasma CVD process

The precursor gas may comprise a metal, in particular boron.

The precursor gas may be triethyl boron, B(C₂H₅)₃, or boron trichloride, BCl₃.

The inert diffusion additive gas may be a noble gas, preferably xenon, Xe.

The inert diffusion additive gas may preferably be of an element having a higher molecular mass than the precursor gas.

The inert diffusion additive gas may be merged with the precursor gas upstream of the reaction zone, preferably in a gas manifold.

The method may further comprise providing at least one carrier gas, wherein the carrier gas is merged with the inert diffusion additive gas and the precursor gas upstream of the reaction zone, preferably in the gas manifold.

The carrier gas may be hydrogen, H₂, or argon, Ar.

The temperature to which the reaction chamber is heated may be greater than about 400° C., preferably about 400° C. to 410° C., or about 410 to 420° C., or about 420° C. to 430° C., or about 430° C. to 440° C., or about 440° C. to 450° C., or about 450° C. to 460° C., or about 460° C. to 470° C., or about 470° C. to 480° C., or about 480° C. to 490° C., or about 490° C. to 500° C., or about 500° C. to 510° C., or about 510° C. to 520° C., or about 520° C. to 530° C., or about 530° C. to 540° C., or about 540° C. to 550° C., or about 550° C. to 560° C., or about 560° C. to 570° C., or about 570° C. to 580° C., or about 580° C. to 590° C., or about 590° C. to 600° C., or about 600° C. to 610° C., or about 610° C. to 620° C., or about 620° C. to 630° C., or about 630° C. to 640° C., or about 640° C. to 650° C., or about 650° C. to 660° C., or about 660° C. to 670° C., or about 670° C. to 680° C., or about 680° C. to 690° C., or about 690° C. to 700° C.

The substrate may be flat, or substantially flat.

The substrate may be a wafer. The material of the wafer may be any type of material used for semiconductor production, such as, but not limited to, silicon, Si. The substrate may have at least one high aspect ratio feature.

The substrate may have high aspect ratio features that are structures in the substrate. The structures may be made in one piece with the substrate when forming the substrate, for example by sintering. Or the structure in the substrate may be made in the substrate at a later stage, for example by etching of the substrate. As another option, the structure having the high aspect ratio features can be formed by deposition of one or more materials on the substrate. The pattern formed by the high aspect ratio features may be a regular pattern that may be in form of holes or trenches or channels at a certain size and at certain distance as to form the pattern.

A high aspect ratio feature may be a hole, a recess, a trench, or a channel.

The inert diffusion additive gas, having a higher partial pressure than the precursor gas, will result in a higher concentration of the inert gas at the top of the high aspect ratio feature. The concentration of the precursor gas will be higher at the bottom of the high aspect ratio feature than at the top. The heavier molecules of the diffusion additive gas push the lighter precursor molecules into recesses and pores of the substrate so as to promote super-conformal deposition, wherein a surface layer of the precursor molecules are deposited on the surface of the high aspect ratio feature and wherein the surface layer is growing at a higher rate at a bottom potion of the high aspect ratio feature than at an opening portion of the high aspect ratio feature.

An aspect ratio of said at least one high aspect ratio feature may be at least about 5:1, at least about 10:1, at least about 20:1 or at least about 40:1.

The aspect ratio is defined for a channel as the ratio between the depth of the channel and the width of the channel. The aspect ratio is defined for a hole as the ratio between the depth of the hole and the diameter of the hole.

The substrate may be a porous body of material.

The porous body of material may have high aspect ratio features constituted by the pores in the material. For example, a porous substrate may be a fabric, a non-woven, a fibrous material or a material with a cellular structure that may be formed by means of a blowing agent or through a sintering process.

The substrate may be a bulk material.

A bulk material may comprise a quantity of particles or granules, which may be arranged on a carrier or which may be caused to flow through the reaction chamber. High aspect ratio features may be formed by voids and/or recesses between particles or granules, or in the form of recesses or through holes in the particles or granules.

According to a second aspect, there is provided a product having a coating which is grown according to the method as described above.

### BRIEF DESCRIPTION OF THE DRAWINGS

FIG. 1 schematically illustrates a device for chemical vapor deposition treatment of a substrate.

FIG. 2 schematically illustrates a substrate having a high aspect ratio feature.

FIGS. 3a-3c schematically illustrate a substrate having a surface layer deposited in a super-conformal growth.

FIGS. 4a-4b are photos which show coating coverage on a polished silicon substrate deposited with triethylboron at 450° C.

FIGS. 5a-5b are photos which show coating coverage on a polished silicon substrate deposited with triethylboron at 550° C.

FIGS. 6a-6b are x-ray photoelectron spectroscopy spectra of the sample showing the peaks for 1 s electrons for boron and carbon.

FIGS. 7a-7f are cross section SEM pictures illustrating the result of deposition at 450° C.

FIGS. 8a-8c are cross section SEM pictures illustrating the result of deposition at 550° C.

### DETAILED DESCRIPTION

The present invention relates to a method of operating a chemical vapor deposition, CVD, process. The method finds application for all sorts of substrates, including planar substrates, 3D-patterned substrates and substrates having one or more high-aspect ratio features. The method finds application for solid substrates as well as for porous substrates and for substrates in the form of a bulk material.

As a non-limiting example, a porous substrate may be a fabric, a non-woven, a fibrous material or a material with a cellular structure that may be formed e.g., by means of a blowing agent or through a sintering process.

A substrate in the form of a bulk material may comprise an amount of particles or granules. High aspect ratio features may be formed by voids or recesses between the particles or granules. Alternatively, or in addition, high aspect ratio features may be formed in or on the at least some of the particles or granules themselves.

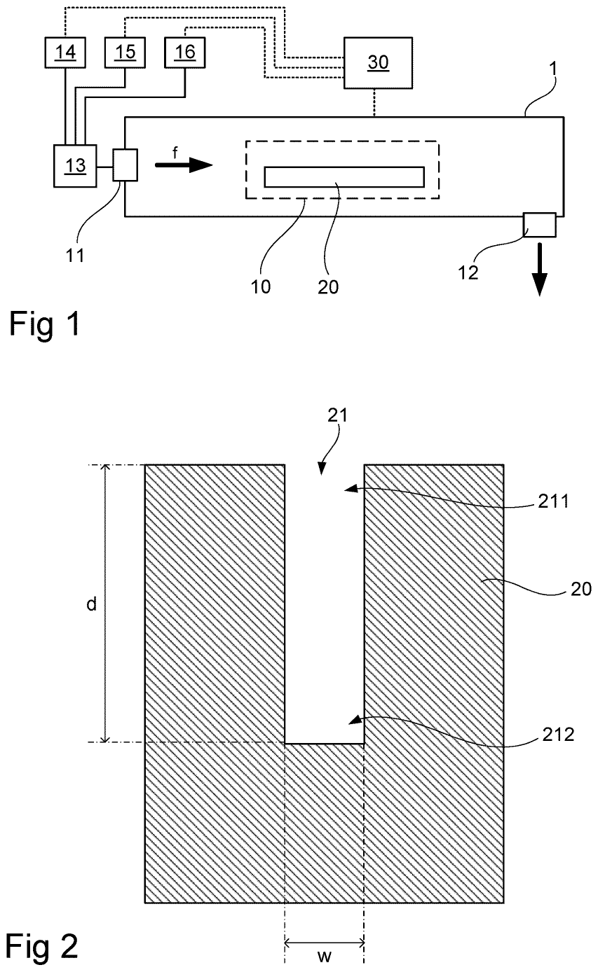

FIG. 1 schematically illustrates a device for chemical vapor deposition treatment of a substrate 20.

A reaction chamber 1 houses a reaction zone 10, wherein the substrate 20 to be treated is aligned. The reaction chamber 1 may, as a non-limiting example, be a horizontal hot-wall CVD reactor.

A controller 30 controls a flow f of a precursor gas from a precursor gas supply 14 and an inert additive gas from an inert additive gas supply 15. The precursor gas and the inert additive gas are mixed at a gas manifold 13 and introduced into the reaction zone 10 of the reaction chamber 1 through a gas inlet 11. The gases react at the surface of the substrate 20 in the reaction zone 10, then by-products and redundant gas are led out through a gas outlet 12.

The precursor gas comprises precursor molecules and the inert diffusion additive comprises inert diffusion additive molecules, wherein the inert diffusion additive molecules have a greater molecular mass than the precursor molecules.

The flow of the inert additive gas from the inert additive gas supply 15 in comparison with the flow of the precursor gas from the precursor gas supply 14 may cause a higher partial pressure of the inert additive gas compared to a partial pressure of the precursor gas, when mixing in the gas manifold 13 and introduced in the reaction chamber 1.

As mentioned by way of introduction, the substrate 20 may be a planar substrate, or a substrate having one or more high-aspect ratio features 21. The substrate may be a porous substrate or a bulk material.

The invention was developed with the primary intention of providing a boron carbide coating on a silicon substrate. Hence, examples and experiments disclosed herein are provided with reference to a boron carbide system. It is, however, believed that the principles of the present invention are applicable also to other coating systems.

The precursor gas may be triethyl boron, B(C₂H₅)₃, or boron trichloride, BCl₃, or any other single-source precursor gas with the desired material for the deposited layer.

The inert additive gas may be a noble gas, such as xenon, Xe.

In some embodiments a carrier gas is used. The controller 30 controls a flow of the carrier gas from a carrier gas supply 16 to mix with the precursor gas and the inert additive gas at the gas manifold 13 upstream of the reaction chamber 1. The carrier gas may be hydrogen, H₂.

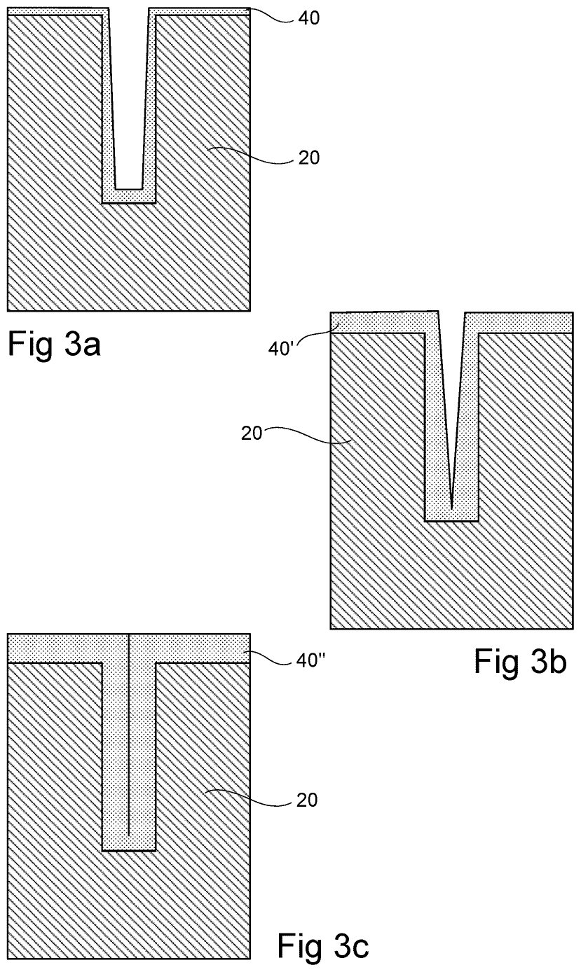

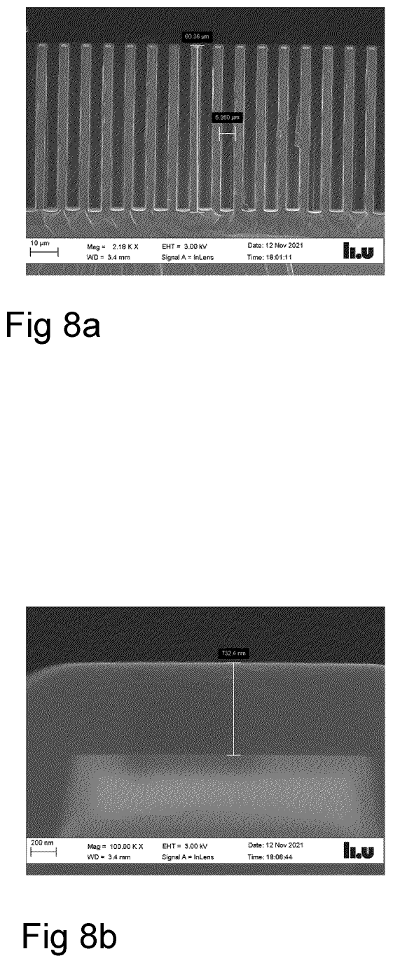

FIG. 2 schematically illustrates a substrate 20 having a high aspect ratio feature 21. High aspect ratio features 21 can be holes, trenches and various porous structures. The structure has a depth d and a width w. The depth d is larger than the width w, wherein the aspect ratio may be at least 5:1 or greater. The high aspect ratio feature 21 of the experiments later explained and displayed in FIGS. 7a-7f has a depth d of 60.97 μm and a width w of 5.982 μm. In some embodiments the width w may be about 100 nm or smaller.

An opening portion 211 of the high aspect ratio feature 21 defines the inlet for gaseous material to be deposited in the structure and is located at one end portion of the structure, at the opposite end portion of the structure a bottom portion 212 of the high aspect ratio feature 21 is located.

A super-conformal growth of a deposited layer, indicates a step-coverage that is greater than 1. The step-coverage is defined as the thickness of the layer at the bottom portion 212 of the high aspect ratio feature 21 divided by the thickness of the layer at the opening portion 211 of the high aspect ratio feature 21.

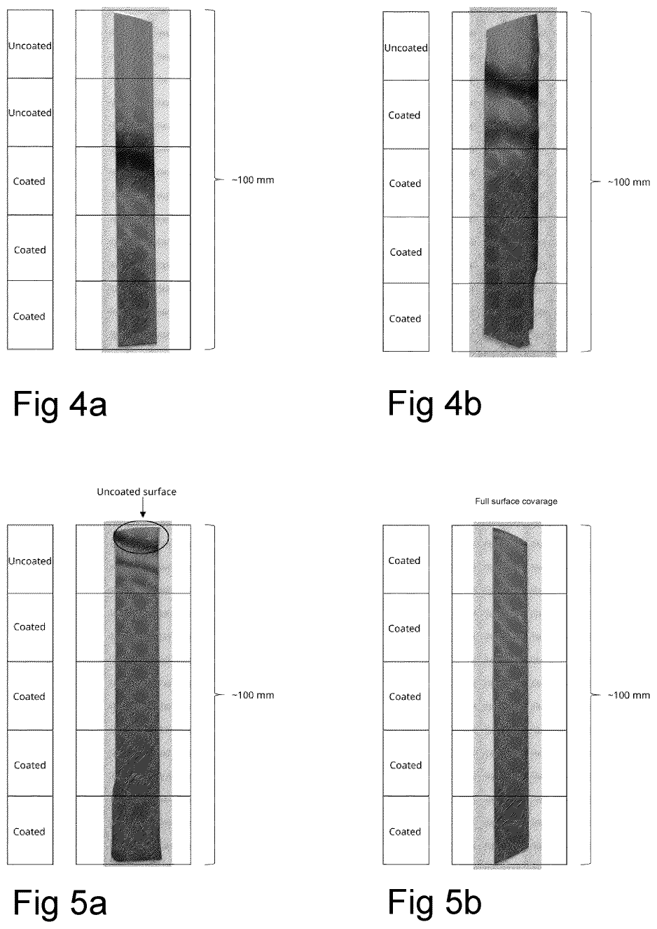

When a super-conformal growth is performed in a CVD process, the layer of the bottom portion 212 will have a faster growth than the layer of the opening portion 211 to obtain a step-coverage greater than 1. This can be schematically illustrated by FIGS. 3a-3c, where a substrate 20 is seen in a cross-sectional view having a surface layer 40, 40′, 40″ deposited in a super-conformal growth.

The growth process may be a continuous process while molecules for deposition is present in the reaction zone 10. In FIG. 3a it is seen that the surface layer 40 has grown faster close to the bottom portion 212 of the high aspect ratio feature. In FIG. 3b the surface layer 40′ of the bottom portion 212 has grown so that the surface layer 40′ forms a V-shape.

As the thickness of the deposited layer is growing on the walls of the hole or trench, the bottom of the V-shape may continue to grow upwards towards the opening portion 211 in the direction of the depth d until the high aspect ratio feature 21 is filled by the surface layer 40″ as seen in FIG. 3c.

### EXAMPLES

Below, there will be provided examples of processes for coating a substrate, incorporating the present inventive concept.

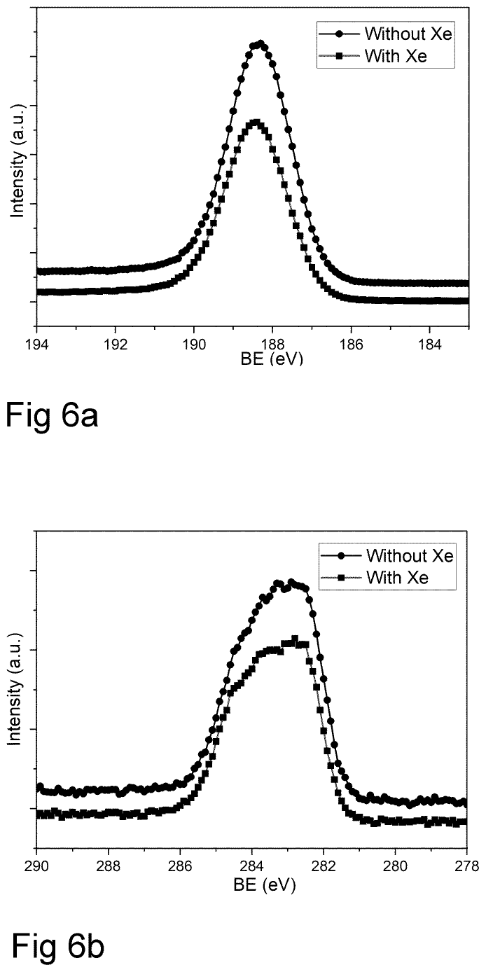

In a first series of experiments, the results of which are shown in FIGS. 4a-4b, 5a-5b and 6a-6b, planar, polished silicon substrates 20 were coated.

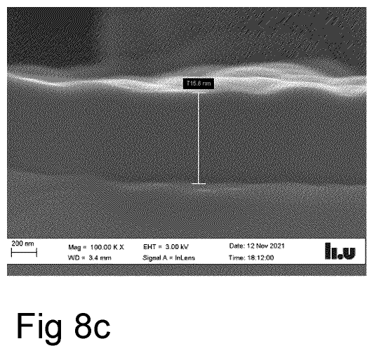

In a second series of experiments, the results of which are shown in FIGS. 7a-7f and 8a-8c, substrates 20 having high aspect ratio features 21 were coated.

Triethyl boron, B(C₂H₅)₃ or TEB, was used as a single source precursor gas and xenon, Xe, was used as an inert diffusion additive gas. For a carrier gas and co-reactant in the process, a palladium membrane purified hydrogen gas, H₂, was used.

The deposition was performed in a reactive zone 10 of a reaction chamber 1, in this example, a horizontal hot-wall CVD reactor. The single source precursor gas was kept in a stainless-steel bubbler in a thermostat bath at 0° C., resulting in a vapour pressure of about 1.65 kPa. The substrate 20 is a silicon, Si, substrate and it was cleaned using an ultrasonic bath, 3 min in acetone and 3 min in ethanol, then rinsed with deionized water and finally blow-dried with nitrogen, N₂, gas. The cleaned Si substrate 20 was loaded into the reaction chamber 1 and subsequently pumped down, back-filled with the carrier gas and heated to deposition temperature. The pressure of the reaction chamber 1 was maintained at about 5 kPa and regulated by a throttle valve on a process pump, and a carrier gas supply 16 delivered a flow of about 2000 sccm of H₂. The process temperature was set to about 500° C.-600° C. and monitored by a pyrometer. TEB gas was delivered by a precursor gas supply 14 at a rate of about 1 sccm to give a partial pressure of about 1.8 Pa, and Xe gas was delivered by an inert additive gas supply 15 at a rate varying from about 10 sccm to about 100 sccm. It results in 1 to 2 order of magnitude higher partial pressure for Xe gas compared to that of TEB gas. The gases were mixed at a gas manifold 13 and introduced to the reaction chamber 1 maintaining a higher partial pressure for the Xe gas compared to the TEB gas.

The reaction takes place in the reaction zone 10, at the surface of the substrate 20, growing the protective layer 40, 40′, 40″. By-products and non-reacted gases are transported out of the reaction chamber 1 by the gas outlet 12.

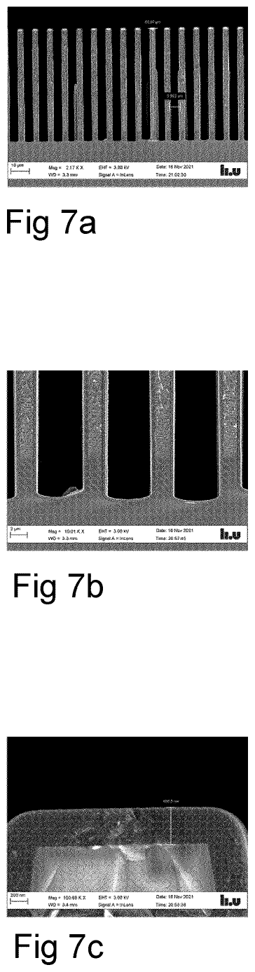

In the first series of experiments a polished Si substrate with 1 cm×10 cm area was used. The substrate 20 was loaded in the reactor chamber 1 in the reaction zone 10 and aligned with the longer side in the gas flow direction f. FIGS. 4a-4b and FIGS. 5a-5b shows BₓC deposited on a polished Si substrate.

In a first part of the first series of experiments, the substrate was coated at a temperature of 450° C. with an H₂ flow rate of 2000 sccm, a TEB gas flow rate of 1 sccm and a pressure of 50 mbar.

One sample was coated without Xe as diffusion additive gas (FIG. 4a) and one sample was coated with an Xe gas at a flow rate of 100 sccm (FIG. 4b).

In a second part of the first series of experiments, the substrate was coated at a temperature of 550° C. with an H₂ flow rate of 2000 sccm, a TEB gas flow rate of 1 sccm and a pressure of 50 mbar.

One sample was coated without Xe as diffusion additive gas (FIG. 5a) and one sample was coated with an Xe flow rate of 100 sccm (FIG. 5b).

In the second series of experiments, a high aspect ratio feature 21 of a Si substrate 20 was provided with a protective surface layer 40, 40′, 40″ of boron carbide, BₓC, deposited in a super-conformal growth process. The growth conditions were the same as explained above and with Xe present as an inert additive gas.

FIGS. 7a-7f show the result of deposition at a temperature of 450° C. and FIGS. 8a-8c show the results of a deposition at 550° C.

### Explanation of the Results

When introducing an inert additive gas in the gas mixture entering the reaction chamber 1, the gas will not take part in the reaction itself, but due to its presence it will force the precursor gas to diffuse further into the reaction zone 10. If the inert additive gas is of a heavier molecule than the precursor gas, this will mean that the diffusion rate of the precursor gas is higher than the diffusion rate for the inert additive gas at thermodynamic equilibrium. During deposition, the pressure of the gases will fall across the substrate 20. By a faster diffusion of the precursor gas and a higher partial pressure for the heavier inert additive gas, the inert additive gas will force the precursor gas to spread away from the gas inlet, the partial pressure of the precursor gas will therefore be higher at the bottom portion of high aspect ratio feature 212 than at the opening portion of high aspect ratio feature 211. This will encourage faster growth at the bottom portion 212 than at the opening portion 211. For the same reasoning, this will enable the molecules of the precursor gas to spread out and cover a larger area of the substrate 20 due to the high partial pressure of the inert additive gas and a larger surface coverage of the deposited layer can be achieved. This is not dependent on whether the substrate 20 has high aspect ratio features or not.

In FIGS. 4a-4b and FIGS. 5a-5b, the 10 cm long Si substrate has been divided into five segments to facilitate a comparison between the samples deposited in Xe free ambient and in the Xe containing ambient.

In FIGS. 4a-4b, where the deposition temperature was 450° C., it can be observed that the sample where deposition has been made with Xe present as an inert additive gas, FIG. 4b, has a larger area of surface coverage than of the sample seen in FIG. 4a, without Xe present. With Xe as inert additive gas present, gas diffusion of TEB were promoted.

In FIGS. 5a-5b, where the deposition temperature was 550° C., there is a better surface coverage for both samples due to higher diffusion rates at an elevated temperature. In FIG. 5a where Xe is not used, a thickness gradient pattern can be seen, as in FIGS. 4a-4b. However, in FIG. 5b were Xe is used as an inert additive gas, the surface coverage is increased and the thickness non-uniformity is reduced.

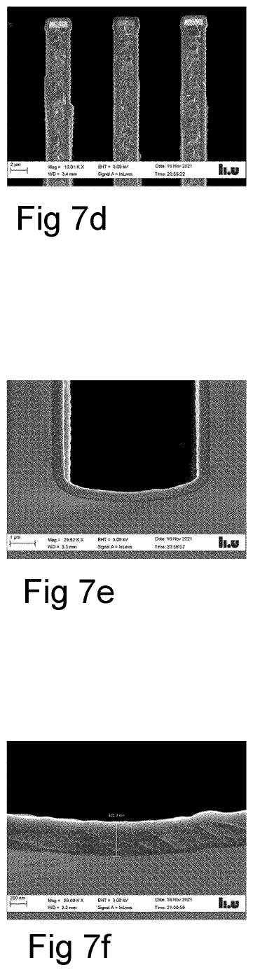

FIGS. 6a-6b are x-ray photoelectron spectroscopy spectra of the sample showing the peaks for 1 s electrons in both Xe free ambient and Xe gas added ambient, for boron in FIG. 6a and carbon in FIG. 6b. It can be observed from the plots that no chemical shift has occurred due to the addition of Xe gas. This result suggests that the addition of Xe gas does not change the chemical environment. While acting as a diffusion additive Xe gas does not influence the deposition chemistry of the deposited film.

FIGS. 7a-7f show the result of deposition of TEB on a Si substrate 20 having high aspect ratio features 21, at a temperature of 450° C.

FIG. 7a shows an 8:1 aspect ratio Si substrate 20. FIG. 7b shows the bottom of the trench in the substrate in FIG. 7a and FIG. 7c shows the top surface of the trench in FIG. 7a.

FIG. 7d shows a magnified view of the top of the trench in FIG. 7a. FIG. 7e shows a magnified view of the bottom surface of the trench in FIG. 7a. FIG. 7f shows a further magnified view of the bottom surface of the trench in FIG. 7a.

By measuring in FIG. 7c it is concluded that a layer thickness at the top of the trench is 436 nm and by measuring in FIG. 7f it is concluded that a layer thickness is 437 nm. Consequently, the experiments disclosed in FIGS. 7a-7f show perfect conformality, approaching super-conformal behaviour.

FIGS. 8a-8c shows the result of deposition of TEB on a Si substrate 20 having high aspect ratio features 21, at a temperature of 550° C.

The measurements at the top of the trench, FIG. 8b, and at the bottom of the trench, FIG. 8c, show a step coverage of 0.78 without xenon as diffusion additive gas and 0.97 with xenon as diffusion additive gas.

The process of super-conformally growing a surface layer 40, 40′, 40″ as schematically seen in FIGS. 3a-3c is performed at a higher temperature than previously known, thus enabling better material properties of the surface layer 40, 40′, 40″.

A precursor gas having molecules with a lower molecular mass than the inert additive gas molecules will enable it to diffuse into a high aspect ratio feature 21 faster than the heavier inert additive gas molecules, thus improving the deposition rate at a bottom portion 212 of the high aspect ratio feature 21.

1.-17. (canceled)

18. A method for operating a chemical vapor deposition, CVD, process, comprising:
providing a substrate in a reaction zone of a reaction chamber,
providing at least one precursor gas flow into the reaction chamber, the precursor gas comprising precursor molecules,
heating the reaction chamber to a temperature that is greater than a reaction onset temperature of the precursor molecules, and
providing at least one inert diffusion additive gas into the reaction chamber, the inert diffusion additive comprising inert diffusion additive molecules,
wherein the inert diffusion additive molecules have a greater molecular mass than the precursor molecules, and
wherein a partial pressure of the inert diffusion additive gas is greater than a partial pressure of the precursor gas.

19. The method according to claim 18, wherein the CVD process is a continuous process.

20. The method according to claim 18, wherein the CVD process is a thermal CVD process.

21. The method according to claim 18, wherein the CVD process is a plasma CVD process.

22. The method according to claim 18, wherein the precursor gas comprises a metal, in particular boron.

23. The method according to claim 22, wherein the precursor gas is triethyl boron, B(C₂H₅)₃, or boron trichloride, BCl3.

24. The method according to claim 18, wherein the inert diffusion additive gas is a noble gas.

25. The method according to claim 18, wherein the inert diffusion additive gas is merged with the precursor gas upstream of the reaction zone.

26. The method according to claim 18, the method further comprises providing at least one carrier gas,
wherein the carrier gas is merged with the inert diffusion additive gas and the precursor gas upstream of the reaction zone.

27. The method according to claim 26, wherein the carrier gas is hydrogen, H₂, or argon, Ar.

28. The method according to claim 18, wherein the temperature to which the reaction chamber is heated is greater than about 400° C. to about 700° C.

29. The method according to claim 18, wherein the substrate is a flat, or substantially flat member.

30. The method according to claim 18, wherein the substrate is a porous body of material.

31. The method according to claim 18, wherein the substrate is a bulk material comprising a plurality of particles or granules.

32. The method according to claim 18, wherein the substrate has at least one high aspect ratio feature.

33. The method according to claim 32, wherein an aspect ratio of said at least one high aspect ratio feature is at least about 5:1, at least about 10:1, at least about 20:1 or at least about 40:1.

34. A product comprising a substrate having a coating which is grown according to the method as claimed in claim 18.

35. The method according to claim 24, wherein the noble gas is xenon, Xe.

36. The method according to claim 25, wherein the inert diffusion additive gas is merged with the precursor gas in a gas manifold.

37. The method according to claim 26, wherein the carrier gas is merged with the inert diffusion additive gas and the precursor gas in a gas manifold.
